(19) United States
(12) Patent Application Publication
(10) Pub. No.: US 2021/0130163 A1
(43) Pub. Date: May 6, 2021

(54) SEMICONDUCTOR DEVICE PACKAGES AND METHODS OF MANUFACTURING THE SAME

(71) Applicant: Advanced Semiconductor Engineering, Inc., Kaohsiung (TW)

(72) Inventors: Yueh-Ju LIN, Kaohsiung (TW); Chih-Cheng HUNG, Kaohsiung (TW); Chin-Song LEE, Kaohsiung (TW); Yun-Chih FEI, Kaohsiung (TW)

(21) Appl. No.: 16/670,790

(22) Filed: Oct. 31, 2019

(51) Int. Cl. B81B 7/00; B81C 1/00; H01L 23/00; H01L 23/31

(52) U.S. Cl. CPC B81B 7/007; B81C 1/00301; H01L 24/48; H01L 24/16; H01L 23/3135; H01L 2924/1811; B81B 2207/012; B81B 2207/098; B81C 2203/0792; H01L 2224/48091; H01L 2224/48225; H01L 23/3121

(57) ABSTRACT

A semiconductor device package includes a redistribution layer structure, a semiconductor component, an encapsulant and a sensing component. The semiconductor component is disposed on a top surface of the RDL structure. The encapsulant covers the semiconductor component, the RDL structure, and an electrical connection member. The sensing component is disposed on a top surface of the encapsulant. The electrical connection member is in contact with a pad of the semiconductor component and has a first surface exposed from the top surface of the encapsulant, and the semiconductor component package includes a wire connecting the sensing component and the first surface of the electrical connection member.

### BACKGROUND

### 1. Field of the Disclosure

The present disclosure relates to semiconductor device packages and methods of manufacturing the same.

### 2. Description of Related Art

MEMS (as used herein, the term “MEMS” may be used to refer to a singular microelectromechanical system or to a plurality of microelectromechanical systems) can be used in semiconductor devices to detect a signal (such as sound, movement or motion, pressure, gas, humidity, temperature, and the like) and to transform the detected signal to an electrical signal.

In comparable three-dimensional semiconductor device packages including a MEMS die and another semiconductor component (such as an application-specific integrated circuit (ASIC) die), the semiconductor component is encapsulated in a substrate. In order to provide electrical connection to an external circuit and the MEMS die stacked over the semiconductor component, an redistribution layer (RDL) structure is formed on both sides of the substrate and tall copper pillars penetrating the substrate and connecting to the two RDL structures should be formed, which increases the manufacturing cost and the overall thickness of the package.

### SUMMARY

According to some embodiments of the present disclosure, a semiconductor device package includes a redistribution layer (RDL) structure, a semiconductor component, an encapsulant and a sensing component. The semiconductor component is disposed on a top surface of the RDL structure. The encapsulant covers the semiconductor component, the RDL structure, and an electrical connection member. The sensing component is disposed on a top surface of the encapsulant. The electrical connection member is in contact with a pad of the semiconductor component and has a first surface exposed from the top surface of the encapsulant, and the semiconductor device package includes a wire connecting the sensing component and the first surface of the electrical connection member.

According to some embodiments of the present disclosure, a semiconductor device package includes a redistribution layer (RDL) structure, a semiconductor component, a dielectric structure and a sensing component. The semiconductor component is disposed on a top surface of the RDL structure and electrically connected to the RDL structure via a first wire. The dielectric structure covers the semiconductor component, the RDL structure, the first wire, and a first electrical connection member. The sensing component is disposed on a top surface of the dielectric structure. The electrical connection member is in contact with a pad of the semiconductor component and exposed from a top surface of the dielectric structure. The semiconductor device package includes a second wire electrically connecting the sensing component and the electrical connection member.

According to some embodiments of the present disclosure, a method of manufacturing a semiconductor device package includes: disposing a semiconductor component on the redistribution layer (RDL) structure, the semiconductor component having an active surface facing away the RDL structure; electrically connecting the active surface of the semiconductor component to the RDL structure; attaching an electrical connection member to the active surface of the semiconductor component; forming a dielectric layer covering the semiconductor component, the RDL structure and the electrical connection member; disposing a sensing component on the dialectical layer; and disposing a wire electrically connecting to the sensing component and the electrical connection member.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may be arbitrarily increased or reduced for clarity of discussion.

FIG. 1 is a cross-sectional view of a semiconductor device package in accordance with some embodiments of the present disclosure.

FIG. 2 is a cross-sectional view of another semiconductor device package in accordance with some embodiments of the present disclosure.

FIG. 3 is a cross-sectional view of another semiconductor device package in accordance with some embodiments of the present disclosure.

FIG. 4 is a cross-sectional view of another semiconductor device package in accordance with some embodiments of the present disclosure.

FIG. 5 is a cross-sectional view of another semiconductor device package in accordance with some embodiments of the present disclosure.

FIG. 6a is an enlarged view of the semiconductor device package in accordance with some embodiments of the present disclosure as illustrated in FIG. 2.

FIG. 6b is a top view of the exposed first surface of the electrical connection member in accordance with some embodiments of the present disclosure.

FIG. 7 is a cross-sectional view of another semiconductor device package in accordance with some embodiments of the present disclosure.

FIG. 8a, FIG. 8b, FIG. 8c, FIG. 8d, FIG. 8e, FIG. 8f, FIG. 8g, FIG. 8h and FIG. 8i illustrate various stages of a method for manufacturing a semiconductor device package in accordance with some embodiments of the present disclosure.

FIG. 9a, FIG. 9b, FIG. 9c, FIG. 9d and FIG. 9e illustrate various stages of a method for manufacturing another semiconductor device package in accordance with some embodiments of the present disclosure.

FIG. 10a, FIG. 10b, FIG. 10c, FIG. 10d and FIG. 10e illustrate various stages of a method for manufacturing another semiconductor device package in accordance with some embodiments of the present disclosure.

FIG. 11a, FIG. 11b, FIG. 11c and FIG. 11d illustrate various stages of a method for manufacturing another semiconductor device package in accordance with some embodiments of the present disclosure.

Common reference numerals are used throughout the drawings and the detailed description to indicate the same or similar components. The present disclosure will be more apparent from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation or disposal of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

The present disclosure describes techniques suitable for the manufacture of smaller semiconductor device packages without the use of tall copper pillars, which can reduce the manufacturing cost and the overall thickness of the packages. As comparing to comparable three-dimensional semiconductor device packages, in some embodiments according to the present disclosure, the semiconductor component (such as an ASIC die) is encapsulated by molding compound, and therefore, the strength of the package can be enhanced. In addition, in some embodiments according to the present disclosure, the RDL structure between the MEMS die and another semiconductor component (such as an ASIC die) can be omitted which can further reduces the manufacturing cost and the overall thickness.

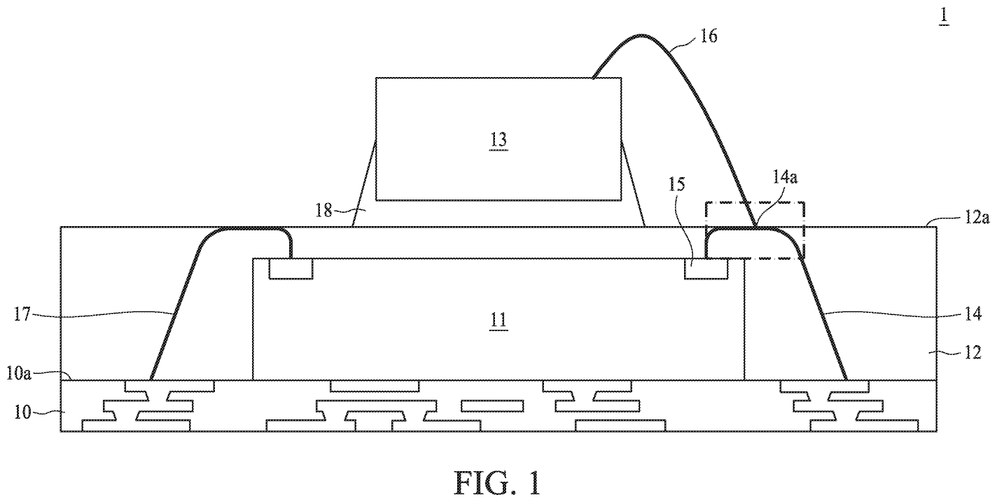

FIG. 1 is a cross-sectional view of a semiconductor device package in accordance with some embodiments of the present disclosure. As shown in FIG. 1, the semiconductor device package 1 includes a redistribution layer (RDL) structure 10, a semiconductor component 11, an encapsulant 12 and a sensing component 13.

The RDL structure 10 may include one or more redistribution layers and insulation material(s) or dielectric material(s) (not denoted in FIG. 1) encapsulating the one or more redistribution layers. The RDL structure 10 may include a fan-out layer. The insulation material(s) or dielectric material(s) may include organic material, solder mask, polyimide (PI), epoxy, Ajinomoto build-up film (ABF), molding compound, or a combination of two or more thereof.

The RDL structure 10 may include conductive trace(s), pad(s), contact(s), via(s) to electrically connect the one or more redistribution layers with each other, or electrically connect the RDL structure to the semiconductor component, or electrically connect the RDL structure to an external circuit or electronic component (not showed).

The semiconductor component 11 is disposed on a top surface 10 a of the RDL structure 10. In some embodiments, the semiconductor component may include one or more semiconductor dies in the form of one or more integrated circuits (ICs) (such as packaged semiconductor dies). In some embodiments, the semiconductor component 11 may include, but is not limited to, at least one active component such as a processor component, a switch component, an application specific IC (ASIC) or another active component. In some embodiments, the semiconductor component 11 may include, but is not limited to, at least one passive component such as a capacitor, a resistor, or the like. In some embodiments, the semiconductor component is not a sensor component.

In some embodiments, the semiconductor device package 1 further includes an electrical connection member 14 in contact with a pad 15 of the semiconductor component 11. The electrical connection member 14 is covered or encapsulated by the encapsulant 12.

The encapsulant 12 is disposed on the RDL structure 10 and covers the semiconductor component 11, the RDL structure 10, and an electrical connection member 14. The encapsulant 12 may include insulation or dielectric material. In some embodiment, the encapsulant 12 be made of molding material that may include, for example, a Novolac-based resin, an epoxy-based resin, a silicone-based resin, or other another suitable encapsulant. Suitable fillers may also be included, such as powdered SiO₂.

The sensing component 13 is disposed on a top surface 12a of the encapsulant 12. In some embodiment, the sensing component 13 may be attached to the top surface 12a of the encapsulant 12 via an adhesion layer 18 (e.g., a die attach film (DAF)). In some embodiments, the sensing component 13 may include a MEMS component, a pressure sensor, a microphone or other electronic component(s).

In some embodiments, the semiconductor device package 1 further includes a wire 16 connecting the sensing component 13 and the first surface 14a of the electrical connection member 14. The sensing component 13 electrically connects to the semiconductor component 11 by the wire 16 and the electrical connection member 14. The electrical connection member 14 is in contact with the wire 16 and the pad 15 of the semiconductor component 11. In some embodiment, the first surface 14a of the electrical connection member 14 has a smallest dimension substantially the same or greater than a diameter of the wire 16 so that an end of the wire 16 can be in good contact with the first surface 14a of the electrical connection member 14. For example, In some embodiment, when the wire 16 has a diameter of 15 μm or less, the first surface 14a of the electrical connection member 14 may have a dimension of 15 μm or more, 20 μm or more, 30 μm or more, 40 μm or more, 50 μm or more, or 60 μm or more.

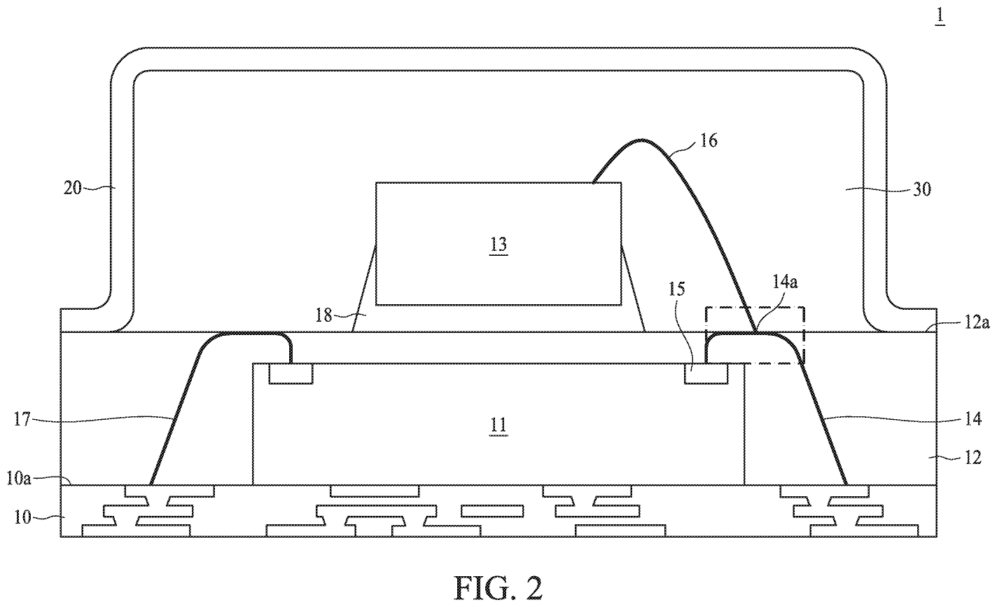

FIG. 2 is a cross-sectional view of a semiconductor device package in accordance with some embodiments of the present disclosure. The semiconductor device package of FIG. 2 has a similar structure to that of the semiconductor device package of FIG. 1 except with respect to the lid 20. As shown in FIG. 2, the semiconductor device package 1 further includes a lid 20. The lid 20 (e.g. a housing) is disposed on the top surface 12a of the encapsulant 12 and defines, together with the encapsulant 12, a cavity 30 to accommodate the sensing component 13. In some embodiments, the lid 20 may have a penetration hole (not shown) to communicate the cavity 30 with the external environment. In some embodiments, the penetration hole may locate, for example, on a top surface of the lid 20. In some embodiments, the lid 20 may include a conductive thin film or a metal layer (e.g., a metal lid), and may include, for example, aluminum, copper, chromium, tin, gold, silver, nickel or stainless steel, or a mixture, an alloy, or other combination thereof. In some embodiments, the lid 20 is a metal lid.

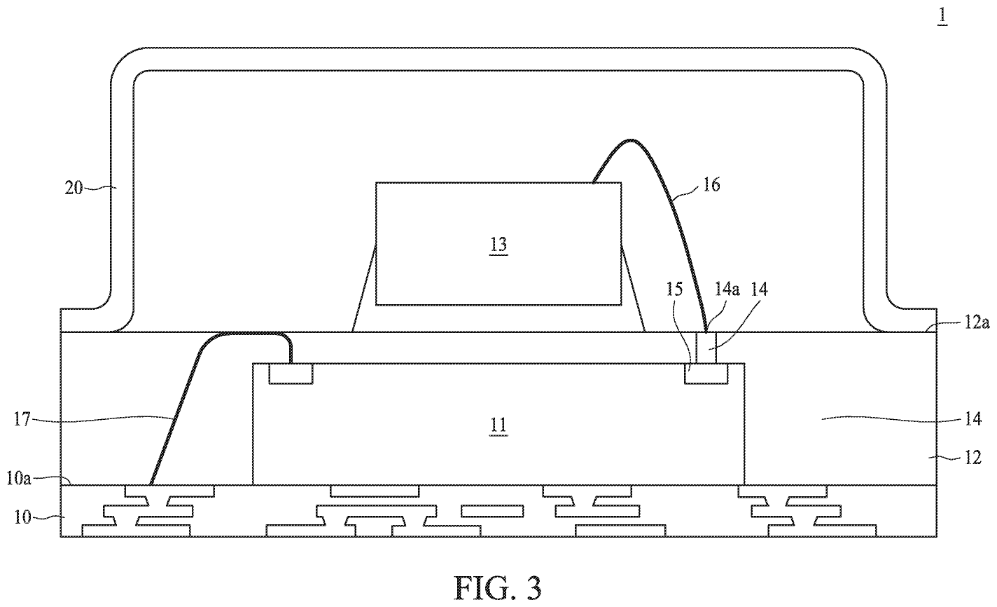

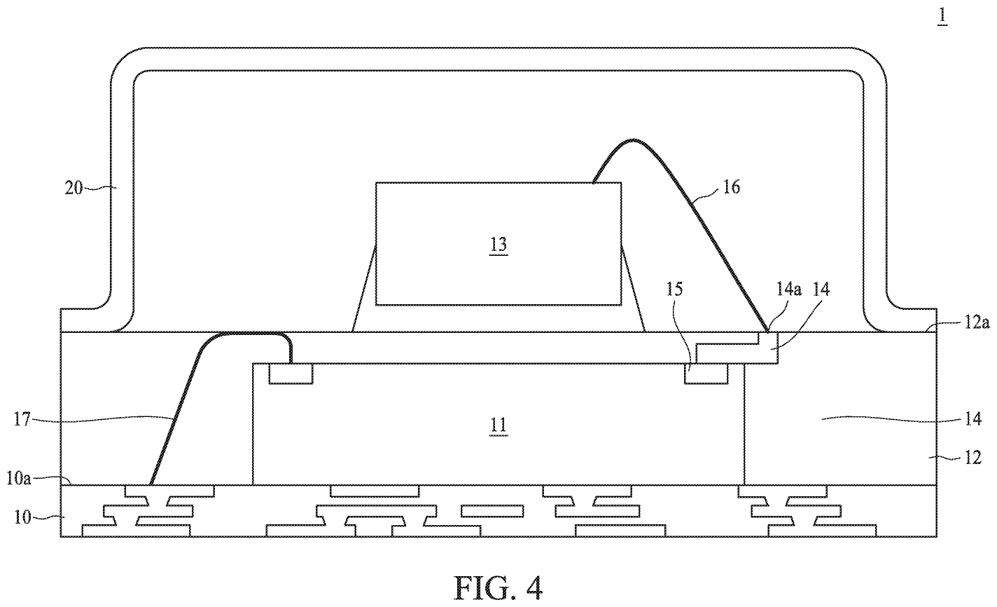

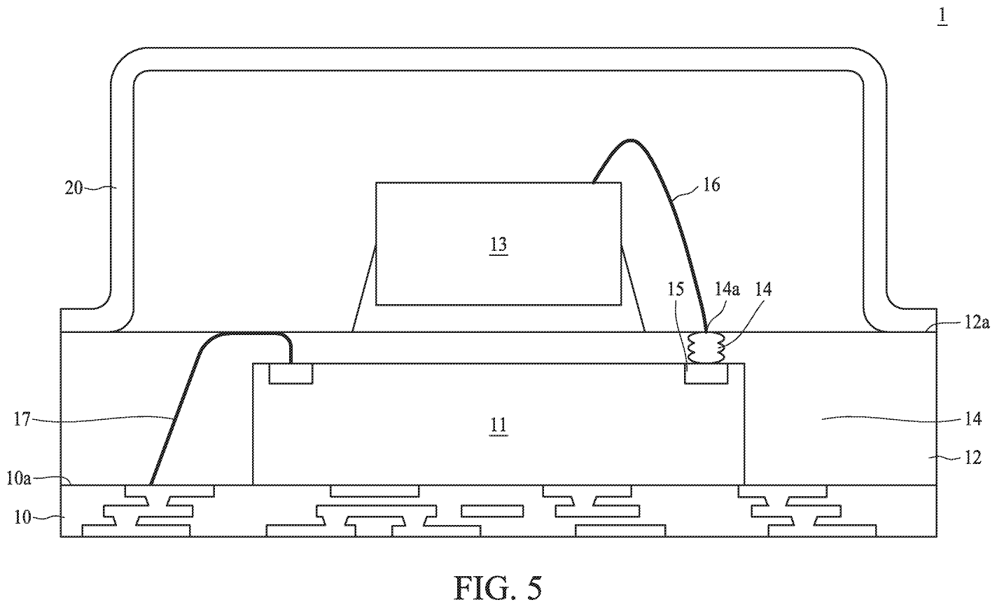

FIG. 3, FIG. 4 and FIG. 5 illustrates a cross-sectional view of a semiconductor device package in accordance with some embodiments of the present disclosure. The semiconductor device package of FIG. 3, FIG. 4 and FIG. 5 is similar to the semiconductor device package of FIG. 2 except the structure of the electrical connection member 14. The electrical connection member 14 may include a wire, a metal pin, a single metal bump or stacked metal bumps. The electrical connection member 14 may be in contact with the wire 16 and the semiconductor component 11, or in contact with the wire 16, the semiconductor component 11 and the RDL structure 10.

In the embodiments illustrated in FIG. 3 and FIG. 4, the electrical connection member 14 is a metal pin connecting to the wire 16 and the RDL structure 10.

In the embodiments illustrated in FIG. 3, the electrical connection member 14 is a straight metal pin. The straight metal pin has a first surface 14a (e.g., a top surface) exposed from the top surface 12a of the encapsulant 12 and in contact with the wire 16 and a bottom surface in contact with the pad 15 of the semiconductor component 11.

In the embodiments illustrated in FIG. 4, the electrical connection member 14 is an L-shape metal pin. The L-shape metal pin includes two metal parts connecting to each other, for example (but not limited to), at an angle of about 90°, and can be formed integrally. One of the metal parts is disposed on the semiconductor component 11 and in contact with the pad 15 of the semiconductor component 11. The other of the metal parts has a surface exposed from the top surface 12a of the encapsulant 12 and in contact with the wire 16. The L-shape metal pin can be configured to provide a fan-in or fan-out connection of the pad 15 of the semiconductor component 11 as specified.

In some embodiments, the electrical connection member 14 may be a single metal bump or stacked metal bumps having a top connecting to the wire 16 and a bottom connecting to the pad 15 of the semiconductor component 11. FIG. 5 illustrates the semiconductor device package where the electrical connection member 14 is stacked metal bumps. The stacked metal bumps may include, for example, but is not limited to, two, three, four, five, six, seven, eight or more bumps stacked on top of each other, and have a first surface 14a (e.g., the topmost surface) exposed from the top surface 12a of the encapsulant 12 and in contact with the wire 16. The metal bump(s) may be formed of the same material from which the wire 16 are formed in some embodiments. However, the metal bump(s) may be formed of a different material than the wire 16 in other embodiments.

Referring back to FIG. 2, in the semiconductor device package illustrated in FIG. 2 the electrical connection member 14 is a wire connecting to the wire 16, the semiconductor component 11 and the RDL structure 10. The wire of the electrical connection member 14 has a first surface 14a exposed from the top surface 12a of the encapsulant 12.

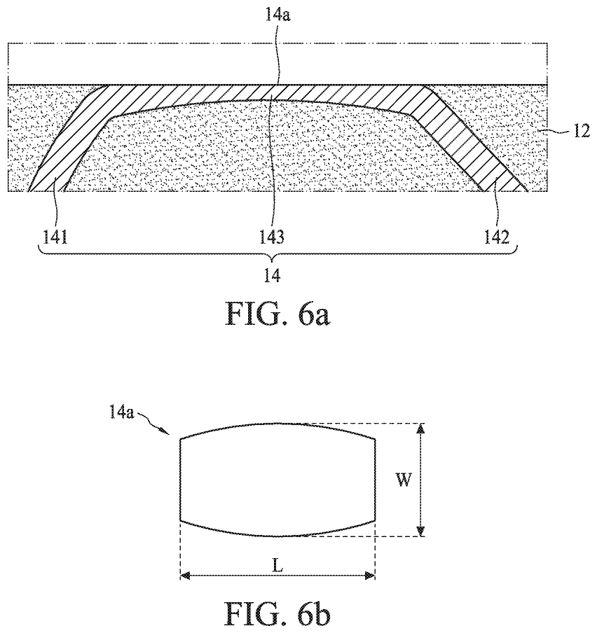

FIG. 6a is an enlarged view of the semiconductor device package in accordance with some embodiments of the present disclosure as illustrated in FIG. 2. As shown in FIG. 6a, the wire of the electrical connection member 14 includes a first vertical segment 141 in contact with the pad 15 of the semiconductor component 11, a second vertical segment 142 in contact with the RDL structure 10, and a horizontal segment 143 in contact with the first vertical segment 141 and the second vertical segment 142. The exposed first surface 14a of the electrical connection member 14 is located on the horizontal segment 143.

FIG. 6b is a top view of the exposed first surface of the electrical connection member in accordance with some embodiments of the present disclosure. As shown in FIG. 6b, the exposed first surface 14a of the electrical connection member 14 has a width w and a length L. The width w (e.g., the smallest dimension) of the exposed first surface 14a is substantially the same or greater than a diameter of the wire 16 so that an end (bottom end) of the wire 16 can be in good contact with the first surface 14a of the electrical connection member 14. For example, in some embodiment, when the wire 16 has a diameter of 15 μm or less, the first surface 14a of the electrical connection member 14 may have a width of 15 μm or more, 20 μm or more, 30 μm or more, 40 μm or more, 50 μm or more, or 60 μm or more.

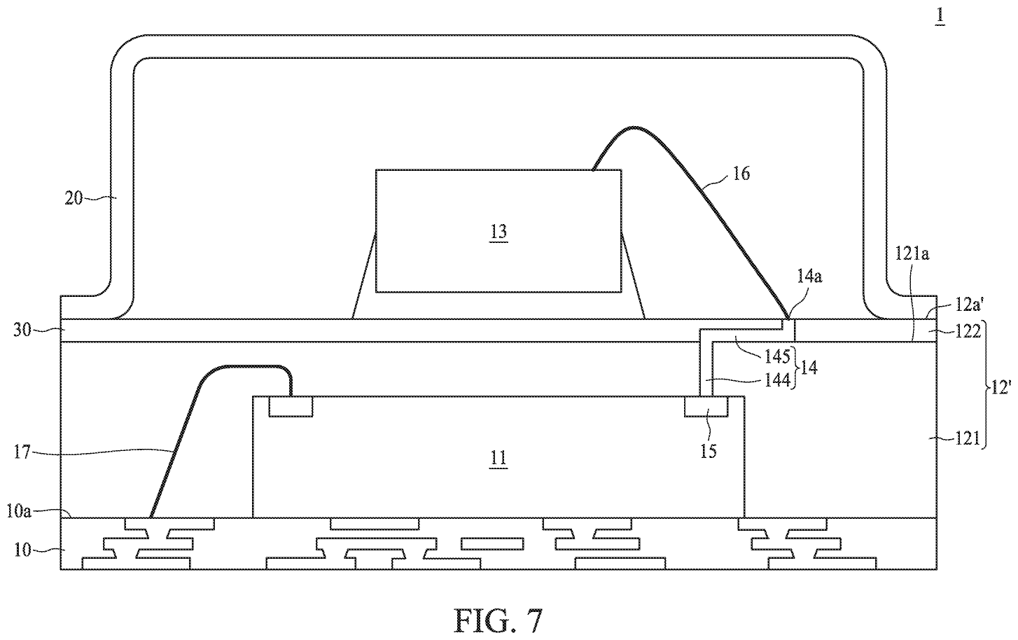

FIG. 7 is a cross-sectional view of another semiconductor device package in accordance with some embodiments of the present disclosure. As shown in FIG. 7, the semiconductor device package 1 includes a redistribution layer (RDL) structure 10, a semiconductor component 11, a dielectric structure 12′ and a sensing component 13. The semiconductor component 11 is disposed on a top surface 10a of the RDL structure 10 and electrically connected to the RDL structure 10 via a first wire 17. The dielectric structure 12′ covers the semiconductor component 11, the RDL structure 10, the first wire 17, and a first electrical connection member 14. The sensing component 13 is disposed on a top surface 12a′ of the dielectric structure 12′. The electrical connection member 14 is in contact with a pad 15 of the semiconductor component 11 and exposed from a top surface 12a′ of the dielectric structure 12′. The semiconductor device package includes a second wire 16 electrically connecting the sensing component 13 and the electrical connection member 14. In some embodiments, the semiconductor device package may further include a lid 20 disposed on a top surface 12a′ of the dielectric structure 12′ to enclose the sensing component 13. Other details of the RDL structure 10, the semiconductor component 11, the sensing component 13 and the lid 20 are as described hereinabove.

In some embodiments, the dielectric structure 12′ may include a first dielectric layer 121 disposed on a top surface 10a of the RDL structure 10 and a second dielectric layer 122 disposed on a top surface 121a of the first dielectric layer 121. The first dielectric layer 121 covers the semiconductor component 11, the RDL structure 10, the first wire 17, and a lower portion of the electrical connection member 14 and the second dielectric layer 122 covers an upper portion of the electrical connection member 14 and exposes a first surface 14a of the electrical connection member 14. The first dielectric layer 121 may be made of molding material that may include, for example, a Novolac-based resin, an epoxy-based resin, a silicone-based resin, or other another suitable encapsulant. Suitable fillers may also be included, such as powdered SiO₂. The second dielectric layer 122 may be formed of the same material from which the first dielectric layer 121 are formed or formed of a different material. In other embodiments, the second dielectric layer 122 is made of a molding compound or polyimide.

In some embodiments, the electrical connection member 14 includes a first surface 14a exposed from a top surface of the dielectric structure 12′ and the first surface 14a has a dimension substantially the same or greater than a diameter of the second wire 16.

In some embodiments, the electrical connection member 14 may be a straight metal pin or an L-shape metal pin as described above or may be designed to have other suitable shapes for providing a fan-in or fan-out connection of the pad 15 of the semiconductor component 11. For example, in the semiconductor device package as illustrated in FIG. 7, the electrical connection member 14 includes an upper portion 145 and a lower portion 144, the lower portion 144 of the electrical connection member 14 is covered by the first dielectric layer 121, and the upper portion 145 of the electrical connection member 14 is covered by the second dielectric layer 122. As shown in FIG. 7, the upper portion 145 of the electrical connection member 14 may include a horizontal segment and a vertical segment, the horizontal segment is laid on the top surface 121a of the first dielectric layer 121 and connects to the lower portion 144 of the electrical connection member 14, and the vertical segment has a bottom connecting to the horizontal segment and a top exposed from a top surface 12a′ of the dielectric structure 12′.

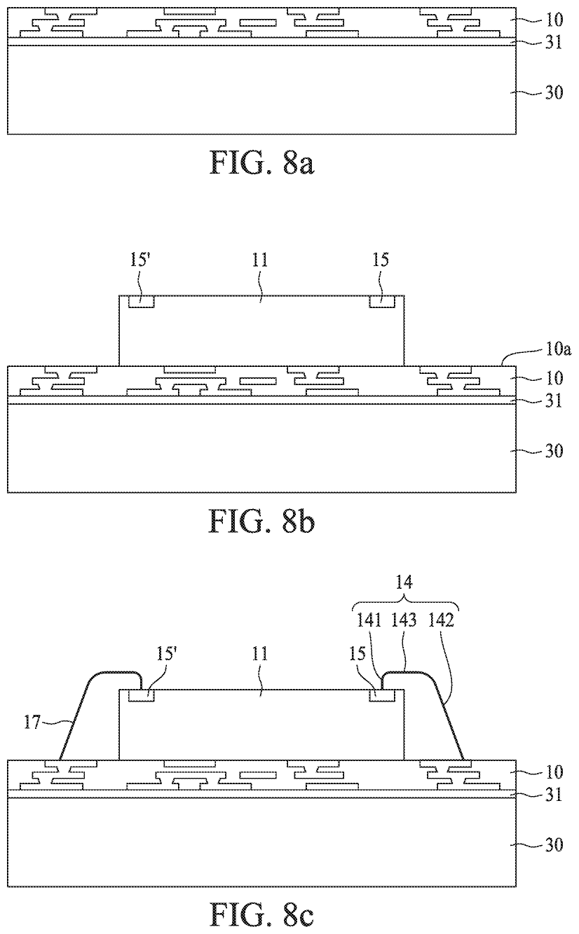

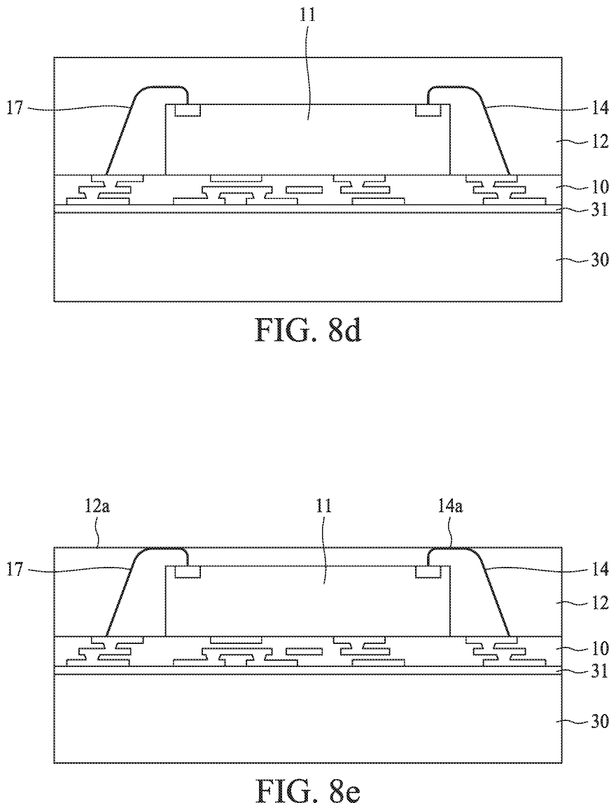

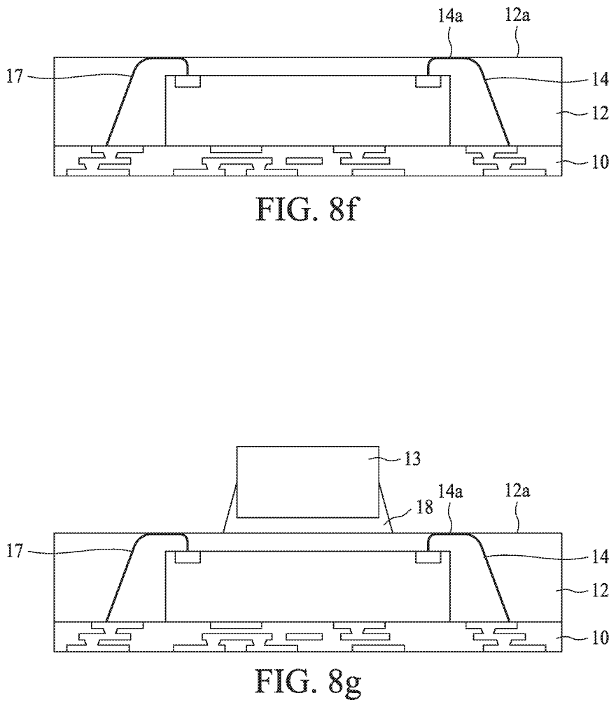

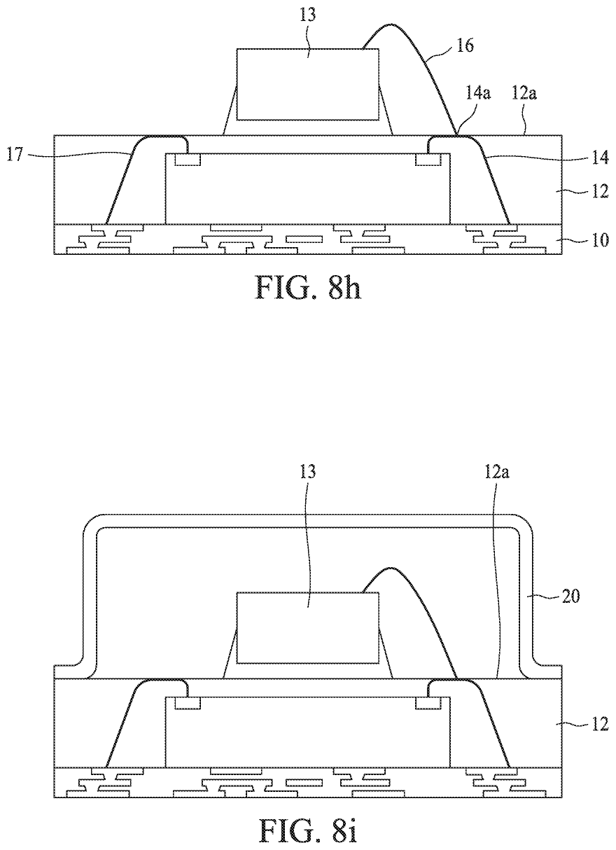

FIG. 8a, FIG. 8b, FIG. 8c, FIG. 8d, FIG. 8e, FIG. 8f, FIG. 8g, FIG. 8h and FIG. 8i illustrate various stages of a method for manufacturing a semiconductor device package in accordance with some embodiments of the present disclosure.

Referring to FIG. 8a, a carrier 30 (e.g., a glass carrier) is provided. The carrier 30 may include a release layer 31 disposed on a top surface of the carrier 30. An RDL structure 10 is formed on the release layer 31 of the carrier 30.

Referring to FIG. 8b, the semiconductor component 11 is disposed on a top surface 10a of the RDL structure 10. The semiconductor component 11 has an active surface facing away the RDL structure. The semiconductor component 11 has a pad 15, 15′ on the active surface.

Referring to FIG. 8c, the pad 15′ on the active surface of the semiconductor component 11 is electrically connected to the RDL structure 10 by a wire 17. An electrical connection member 14 is attached to the active surface of the semiconductor component 11. In the embodiments illustrated in FIG. 8c, the electrical connection member 14 is a wire and electrically connected to the RDL structure 10 and the pad 15 of the semiconductor component 11. The wire of the electrical connection member 14 may include a first vertical segment 141 in contact with the pad 15 of the semiconductor component 11, a second vertical segment 142 in contact with the RDL structure 10, and a horizontal segment 143 in contact with the first vertical segment 141 and the second vertical segment 142.

Referring to FIG. 8d, a dielectric layer 12 is formed, for example, by molding a compound to cover the semiconductor component 11, the RDL structure 10, the electrical connection member 14 and the wire 17.

Referring to FIG. 8e, the dielectric layer 12 is ground to reduce its thickness. A portion of the electrical connection member 14 is ground at the same time so that a surface 14a of the electrical connection member 14 is exposed from the surface 12a of dielectric layer 12 after grinding. The size of the exposed surface 14a can be controlled by grinding, and in some embodiments, the exposed surface 14a has a smallest dimension substantially the same or greater than a diameter of the wire 16 to be formed on the exposed surface 14a in subsequent steps. In some embodiments, the exposed surface 14a of the electrical connection member 14 is located on the horizontal segment 143.

After the stage illustrated in FIG. 8e, the carrier 30 and the release layer 31 are removed as illustrated in FIG. 8f.

Referring to FIG. 8g, a sensing component 13 is disposed on the surface 12a of dielectric layer 12. In some embodiments, the sensing component 13 may be attached or bonded on the surface 12a of dielectric layer 12 via a adhesion layer 18.

Referring to FIG. 8h, a wire 16 is disposed and electrically connects to the sensing component 13 and the electrical connection member 14. The wire 16 is in contact with the sensing component 13 at one end and in contact with the exposed surface 14a of the electrical connection member 14 at the other end.

Referring to FIG. 8i, a lid 20 (e.g., a housing) is disposed on the surface 12a of dielectric layer 12 to enclose the sensing component 13.

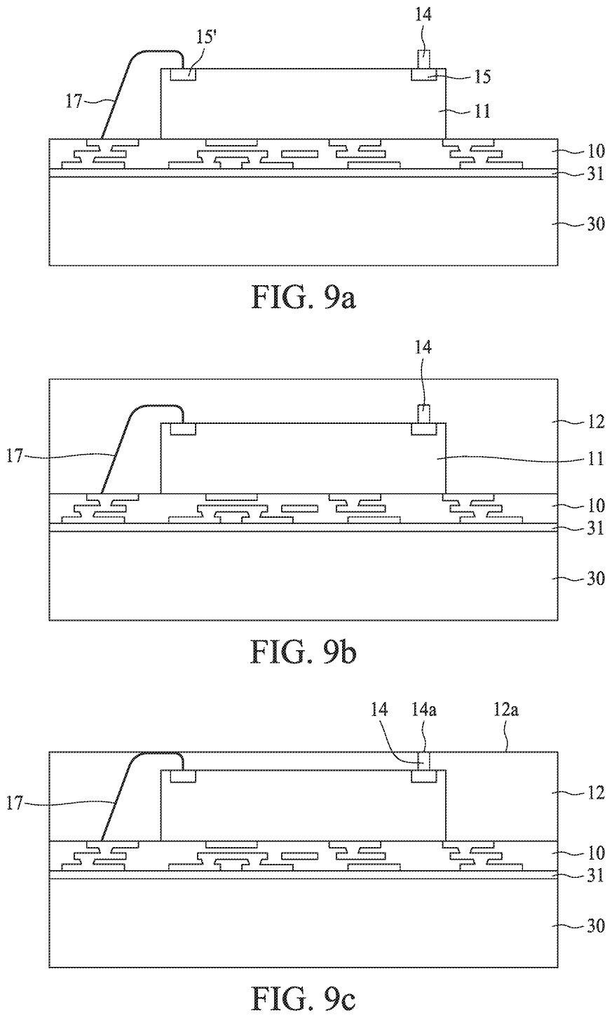

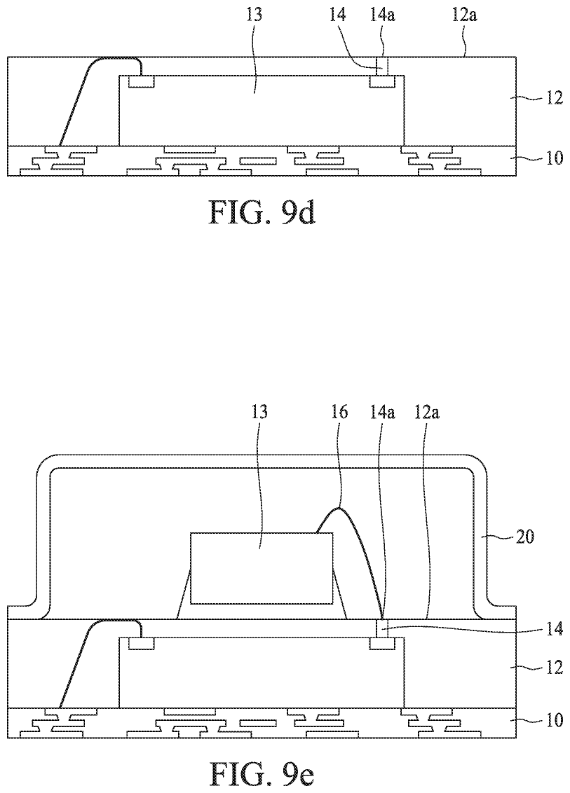

FIG. 8a, FIG. 8b, FIG. 9a, FIG. 9b, FIG. 9c, FIG. 9d and FIG. 9e illustrate various stages of a method for manufacturing another semiconductor device package in accordance with some embodiments of the present disclosure.

First, a semiconductor component 11 is disposed on a top surface 10a of an RDL structure 10 in accordance with the method illustrated in FIG. 8a and FIG. 8b.

Referring to FIG. 9a, the pad 15′ on the active surface of the semiconductor component 11 is electrically connected to the RDL structure 10 by a wire 17. An electrical connection member 14 is attached to the active surface of the semiconductor component 11. In the embodiments illustrated in FIG. 9a, the electrical connection member 14 is a metal pin (e.g., a straight metal pin) and a bottom surface of the metal pin is in contact with the pad 15 of the semiconductor component 11 to provide electrical connection. The shape and size of the metal pin can be adjusted as specified.

Referring to FIG. 9b, a dielectric layer 12 is formed, for example, by molding a compound to cover the semiconductor component 11, the RDL structure 10, the electrical connection member 14 and the wire 17.

Referring to FIG. 9c, the dielectric layer 12 is ground to reduce its thickness and exposed a surface 14a of the electrical connection member 14. In some embodiment, a portion of the electrical connection member 14 may be ground together with the dielectric layer 12 to reduce the thickness of the electrical connection member 14. The surface 14a of the electrical connection member 14 is exposed from the surface 12a of dielectric layer 12 after grinding. The exposed surface 14a has a smallest dimension substantially the same or greater than a diameter of the wire 16 to be formed on the exposed surface 14a in subsequent steps.

The carrier 30 and the release layer 31 are removed as illustrated in FIG. 9d.

Referring to FIG. 9e, a sensing component 13 is disposed on the surface 12a of dielectric layer 12, a wire 16 is disposed and electrically connects to the sensing component 13 and the electrical connection member 14, a lid 20 (e.g., a housing) is disposed on the surface 12a of dielectric layer 12 in accordance with the method as illustrated in FIG. 8g, FIG. 8h and FIG. 8i.

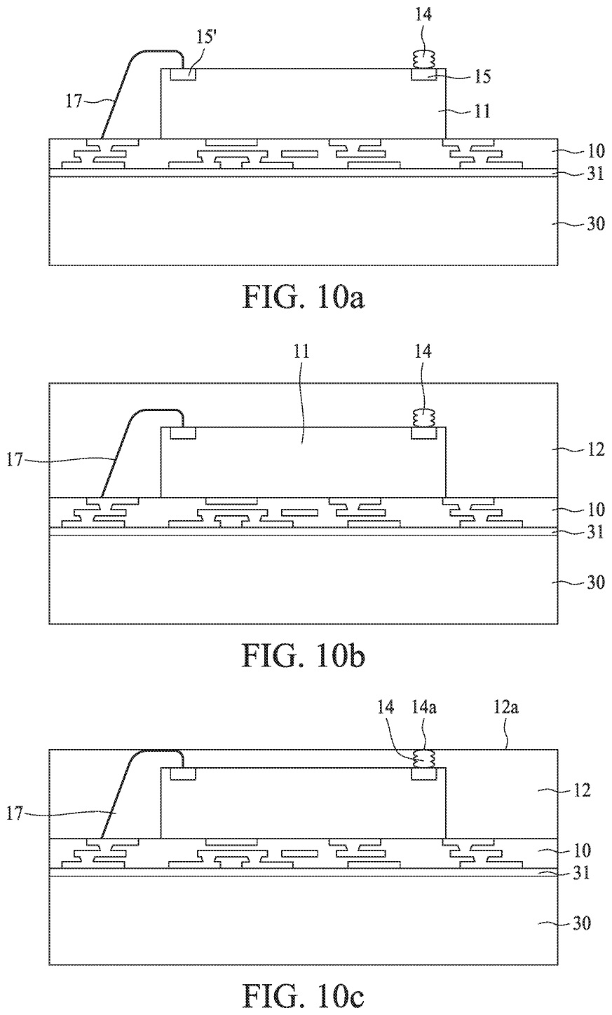

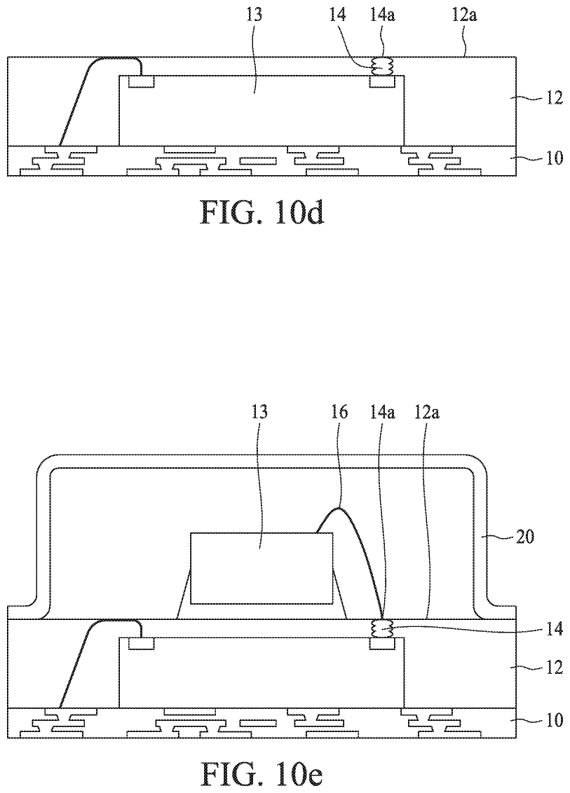

FIG. 8a, FIG. 8b, FIG. 10a, FIG. 10b, FIG. 10c, FIG. 10d and FIG. 10e illustrate various stages of a method for manufacturing another semiconductor device package in accordance with some embodiments of the present disclosure.

First, a semiconductor component 11 is disposed on a top surface 10a of an RDL structure 10 in accordance with the method illustrated in FIG. 8a and FIG. 8b.

Referring to FIG. 10a, the pad 15′ on the active surface of the semiconductor component 11 is electrically connected to the RDL structure 10 by a wire 17. An electrical connection member 14 is attached to the active surface of the semiconductor component 11. In the embodiments illustrated in FIG. 10a, the electrical connection member 14 is stacked metal bumps and a bottom surface of the stacked metal bumps is in contact with the pad 15 of the semiconductor component 11 to provide electrical connection. The number of the metal bumps and the diameter of each metal bump can be adjusted as specified.

Referring to FIG. 10b, a dielectric layer 12 is formed, for example, by molding a compound to cover the semiconductor component 11, the RDL structure 10, the electrical connection member 14 and the wire 17.

Referring to FIG. 10c, the dielectric layer 12 is ground to reduce its thickness and exposed a surface 14a of the electrical connection member 14. In some embodiment, a portion of the electrical connection member 14 may be ground together with the dielectric layer 12 to reduce the thickness of the electrical connection member 14. The surface 14a of the electrical connection member 14 is exposed from the surface 12a of dielectric layer 12 after grinding. The exposed surface 14a has a smallest dimension substantially the same or greater than a diameter of the wire 16 to be formed on the exposed surface 14a in subsequent steps.

The carrier 30 and the release layer 31 are removed as illustrated in FIG. 10d.

Referring to FIG. 10e, a sensing component 13 is disposed on the surface 12a of dielectric layer 12, a wire 16 is disposed and electrically connects to the sensing component 13 and the electrical connection member 14, a lid 20 (e.g., a housing) is disposed on the surface 12a of dielectric layer 12 in accordance with the method as illustrated in FIG. 8g, FIG. 8h and FIG. 8i.

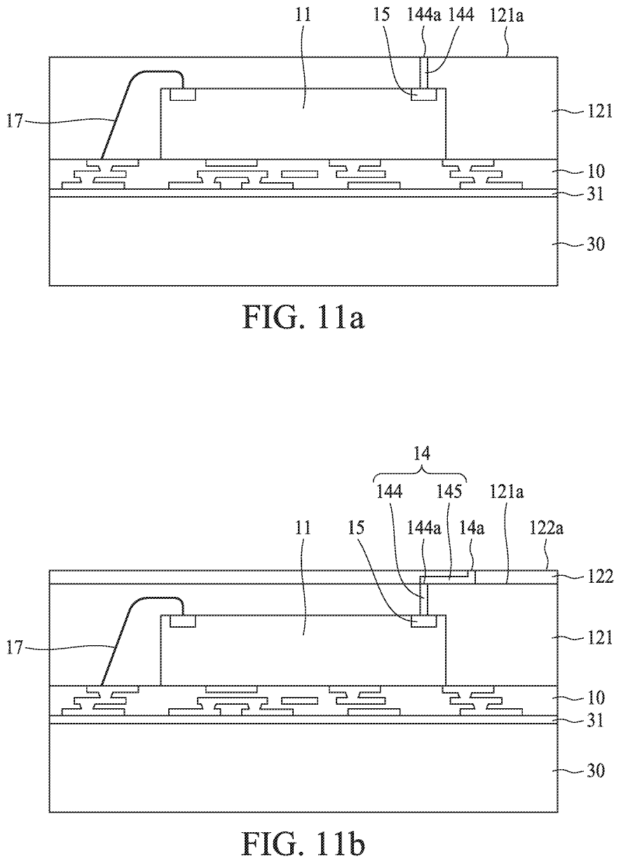

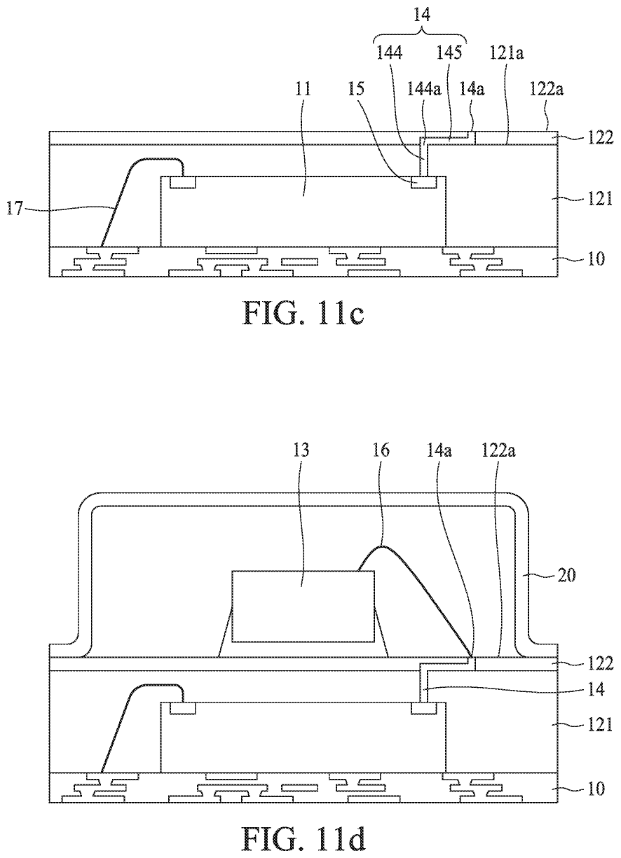

FIG. 11a, FIG. 11b, FIG. 11c and FIG. 11d illustrate various stages of a method for manufacturing another semiconductor device package in accordance with some embodiments of the present disclosure.

Referring to FIG. 11a, a semiconductor device package prepared by the method illustrated in FIG. 9a, FIG. 9b and FIG. 9c is provided. The top surface 144a of the straight metal pin 144 is exposed from the top surface 121a of a first dielectric layer 121.

In the stage illustrated in FIG. 11b, an extension portion 145 of the straight metal pin 144 and a second dielectric layer 122 may be formed. The extension portion 145 and the straight metal pin 144 constitute the electrical connection member 14. In view of the size and/or arrangement of the semiconductor component 11 and the sensing component 13, the extension portion 145 can be designed to provide a fan-out or fan-in connection of the semiconductor component 11. In some embodiments, the extension portion 145 may include, for example, a horizontal segment and a vertical segment, the horizontal segment is laid on the top surface 121a of the first dielectric layer 121 and connects to the exposed surface 144a of the straight metal pin 144, and the vertical segment has a bottom connecting to the horizontal segment. In some embodiments, the extension portion 145 and the second dielectric layer 122 may be formed, for example, by a process for forming a patterned conductive layer and under bump metallurgy (UBM). The second dielectric layer 122 may be ground to reduce its thickness and exposed a surface 14a of the electrical connection member 14 from a surface 122a of the second dielectric layer 122.

The carrier 30 and the release layer 31 are removed as illustrated in FIG. 11c.

Referring to FIG. 11d, a sensing component 13 is disposed on the surface 122a of the second dielectric layer 122, a wire 16 is disposed and electrically connects to the sensing component 13 and the electrical connection member 14, a lid 20 (e.g., a housing) is disposed on the surface 122a of the second dielectric layer 122 in accordance with the method as illustrated in FIG. 8g, FIG. 8h and FIG. 8i.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only and that practical implementations of the structures described herein can be spatially arranged in any orientation or manner, provided that the merits of embodiments of this disclosure are not deviated from by such an arrangement.

As used herein, the term “vertical” is used to refer to these upward and downward directions, whereas the term “horizontal” refers to directions transverse to the vertical directions.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between the highest point and the lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit, and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A semiconductor device package, comprising:
a redistribution layer (RDL) structure;
a semiconductor component disposed on a top surface of the RDL structure;
an encapsulant covering the semiconductor component, the RDL structure, and an electrical connection member; and
a sensing component disposed on a top surface of the encapsulant,
wherein the electrical connection member is in contact with a pad of the semiconductor component and has a first surface exposed from the top surface of the encapsulant, and wherein the semiconductor device package further comprises a wire connecting the sensing component and the first surface of the electrical connection member.

2. The semiconductor device package of claim 1, further comprising a lid enclosing the sensing component.

3. The semiconductor device package of claim 1, wherein the first surface of the electrical connection member has a smallest dimension substantially the same or greater than a diameter of the wire connecting the sensing component and the first surface of the electrical connection member.

4. The semiconductor device package of claim 1, wherein the electrical connection member is a wire comprising a first vertical segment in contact with the pad of the semiconductor component, a second vertical segment in contact with the RDL structure, and a horizontal segment in contact with the first vertical segment and the second vertical segment.

5. The semiconductor device package of claim 4, wherein the exposed first surface of the electrical connection member is located on the horizontal segment.

6. The semiconductor device package of claim 4, wherein the exposed first surface of the electrical connection member has a width substantially the same or greater than a diameter of the wire connecting the sensing component and the first surface of the electrical connection member.

7. The semiconductor device package of claim 1, wherein the electrical connection member is a metal pin.

8. The semiconductor device package of claim 1, wherein the electrical connection member is a single bump or stacked metal bumps.

9. A semiconductor device package, comprising:
a redistribution layer (RDL) structure;
a semiconductor component disposed on a top surface of the RDL structure and electrically connected to the RDL structure via a first wire;
a dielectric structure covering the semiconductor component, the RDL structure, the first wire, and a first electrical connection member; and
a sensing component disposed on a top surface of the dielectric structure,
wherein the electrical connection member is in contact with a pad of the semiconductor component and exposed from a top surface of the dielectric structure, and wherein the semiconductor device package further comprises a second wire electrically connecting the sensing component and the electrical connection member.

10. The semiconductor device package of claim 9, further comprising a lid enclosing the sensing component.

11. The semiconductor device package of claim 9, wherein the dielectric structure comprises a first dielectric layer disposed on a top surface of the RDL structure and a second dielectric layer disposed on a top surface of the first dielectric layer.

12. The semiconductor device package of claim 11, wherein the second dielectric layer and the first dielectric layer are made of a same material.

13. The semiconductor device package of claim 11, wherein the first dielectric layer covers the semiconductor component, the RDL structure, the first wire, and a lower portion of the electrical connection member.

14. The semiconductor device package of claim 11, wherein the second dielectric layer covers an upper portion of the electrical connection member and exposes a first surface of the electrical connection member.

15. The semiconductor device package of claim 14, wherein the upper portion of the electrical connection member comprises a horizontal segment and a vertical segment, the horizontal segment connects to the lower portion of the electrical connection member and the vertical segment has a top exposed from a top surface of the second dielectric layer.

16. The semiconductor device package of claim 9, wherein the electrical connection member comprises a first surface exposed from a top surface of the dielectric structure and the first surface has a dimension substantially the same or greater than a diameter of the second wire.

17. A method of manufacturing a semiconductor device package, comprising:
disposing a semiconductor component on the redistribution layer (RDL) structure, wherein the semiconductor component has an active surface facing away the RDL structure;
electrically connecting the active surface of the semiconductor component to the RDL structure;
attaching an electrical connection member to the active surface of the semiconductor component;
forming a dielectric layer covering the semiconductor component, the RDL structure and the electrical connection member;
disposing a sensing component on the dialectical layer; and
disposing a wire electrically connecting to the sensing component and the electrical connection member.

18. The method of claim 17, wherein the electrical connection member has a first surface in contact with the wire.

19. The method of claim 18, wherein the first surface of the electrical connection member has a smallest dimension substantially the same or greater than a diameter of the wire.

20. The method of claim 17, further comprising disposing a lid enclosing the sensing component.
